(19) United States
(12) Patent Application Publication
(10) Pub. No.: US 2018/0192531 A1
(43) Pub. Date: Jul. 5, 2018

(54) ELECTRONIC DEVICE, CONNECTOR, AND ELECTRONIC DEVICE ASSEMBLY

(71) Applicants: Fu Tai Hua Industry (Shenzhen) Co., Ltd., Shenzhen (CN); HON HAI PRECISION INDUSTRY CO., LTD., New Taipei (TW)

(72) Inventors: Gang-Hua Liu, Shenzhen (CN); Hao-Yuan Huang, New Taipei (TW); Chia-Jui Hu, New Taipei (TW); Chun-Kai Peng, New Taipei (TW)

(21) Appl. No.: 15/841,794

(22) Filed: Dec. 14, 2017

(30) Foreign Application Priority Data
Dec. 29, 2016 (CN) 201611250071.2

(51) Int. Cl. H05K 5/02; H01R 9/24; H01R 13/62

(52) U.S. Cl. CPC H05K 5/0247; H05K 2203/104; H01R 13/6205; H01R 9/24

(57) ABSTRACT

An electronic device includes a case and a plug. The case has an end wall to which the plug can be firmly held by magnetism. The plug matches output and input ports arranged on the end wall and includes a power transmission adapter, a ground adapter, a video transmission adapter, an audio transmission adapter, and a data transmission adapter, for transmitting power, grounding, transmitting video, audio, and data to the electronic device. A connector and an electronic device assembly are also provided.

### FIELD

The subject matter herein generally relates to an electronic device assembly, and especially relates to an electronic device connecting to multiple electronic apparatus via a connector.

### BACKGROUND

Portable electronic devices can include an earphone jack, a power jack, a USB jack, an audio output hole, and other interfaces. However, the portable electronic device with so many holes/jacks, when spread around the case of the portable electronic device, weakens the structural strength of the portable electronic device as well as not being aesthetically pleasing.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is a block diagram of one exemplary embodiment of an electronic device assembly.

FIG. 2 is an isometric view of one exemplary embodiment of the electronic device assembly.

FIG. 3 is an isometric view of one exemplary embodiment of an electronic device.

FIG. 4 is an isometric view of one exemplary embodiment of a connector.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like. The term “coupled” is defined as connected, whether directly or indirectly through intervening components, and is not necessarily limited to physical connections. The connection can be such that the objects are permanently connected or releasably connected.

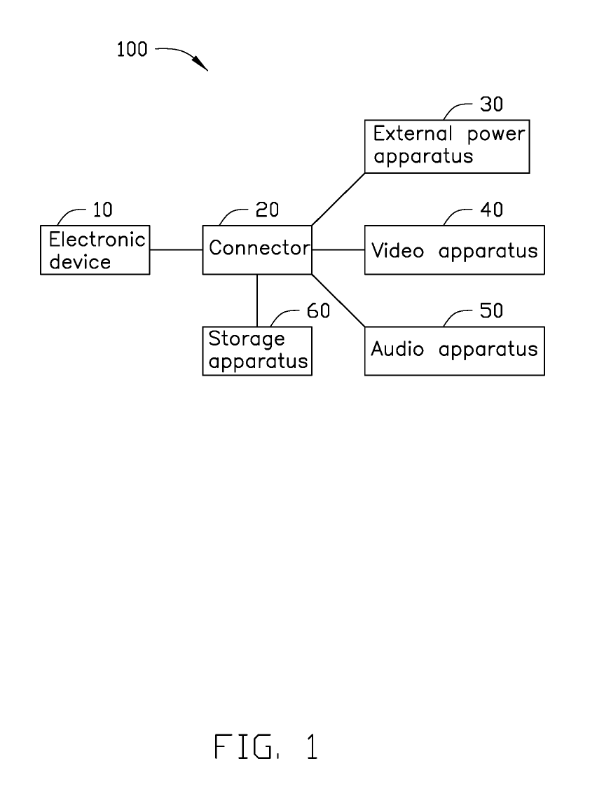

FIG. 1 illustrates one exemplary embodiment of an electronic device assembly 100 including an electronic device 10 and a connector 20. The connector 20, connected to the electronic device 10, may be electronically connected to an external power apparatus 30, a video apparatus 40, an audio apparatus 50, and a storage apparatus 60. Thereby, power, video, audio, and data can be transmitted to the electronic device 10. The electronic device 10 can be, but is not limited to, a mobile phone, a personal digital assistant, or a tablet computer.

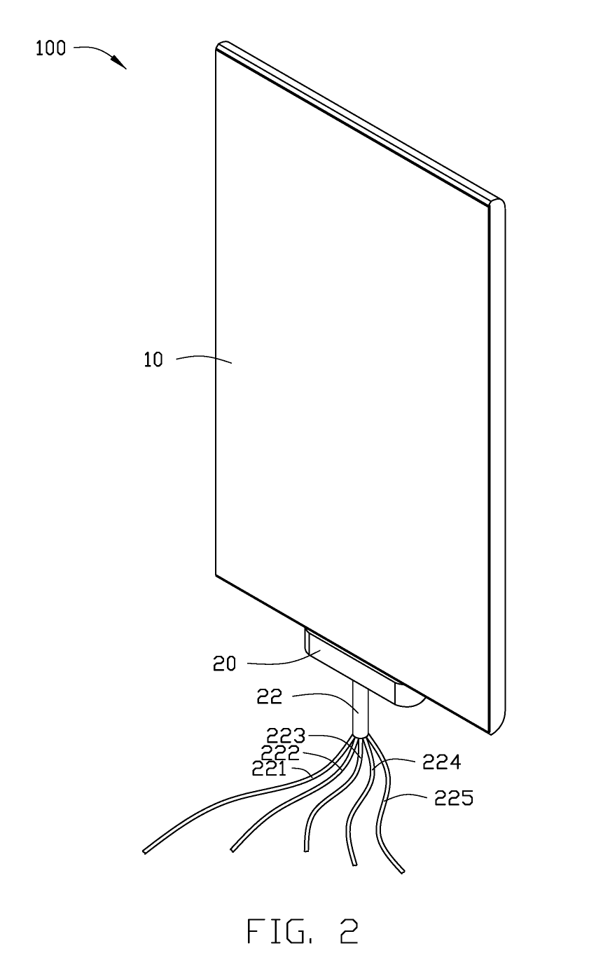

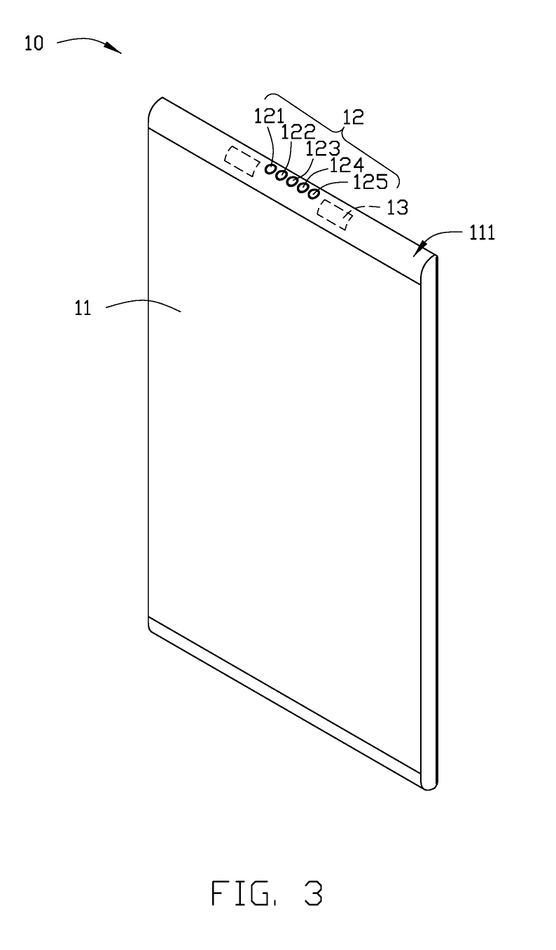

Referring to FIGS. 2 and 3, the electronic device 10 includes a case 11. The case 11 is substantially a hollow rectangular body. In at least one embodiment, the case 11 is made of metal material, such as titanium alloy, magnesium alloy, aluminum alloy, stainless steel, etc. The case 11 includes an end wall 111 and a plug 12. The end wall 111 is substantially an arcuate surface. The plug 12 is coupled to a central portion of the end wall 111. The plug 12 includes a power transmission adapter 121, a ground adapter 122, a video transmission adapter 123, an audio transmission adapter 124, and a data transmission adapter 125 for transmitting power, grounding, transmitting video, audio, and data to the electronic device 10, respectively. The power transmission adapter 121, the ground adapter 122, the video transmission adapter 123, the audio transmission adapter 124, and the data transmission adapter 125 are cylindrical and slightly protruding from the end wall 111. The power transmission adapter 121, the ground adapter 122, the video transmission adapter 123, the audio transmission adapter 124, and the data transmission adapter 125 are arranged in a line, for example with their centers on a common line.

The electronic device 10 further includes at least one first magnet element 13. The first magnet element 13 is arranged in the end wall 111. In at least one embodiment, the electronic device 10 includes two first magnet elements 13 symmetrically arranged on opposite ends of the plug 12. Each of the first magnet elements 13 is substantially rectangular and can be a magnet or made of magnetic material.

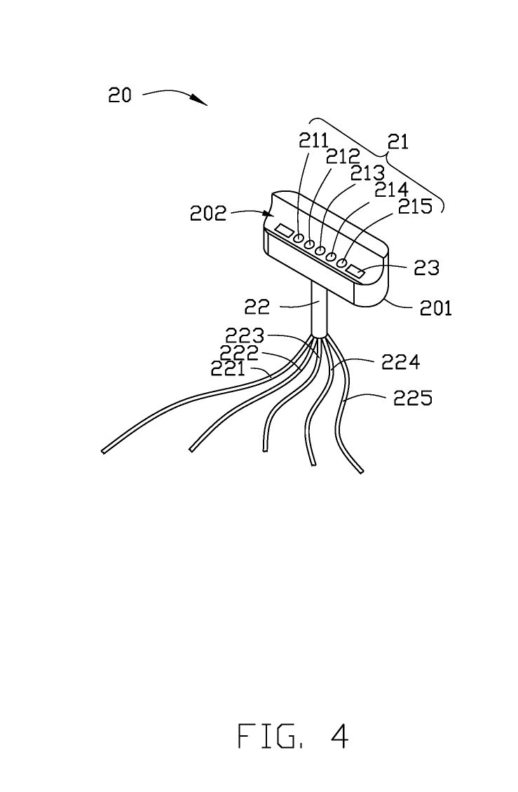

Referring to FIG. 4, the connector 20 includes a contact assembly 21 and a wire assembly 22 electronically connected to the contact assembly 21. The contact assembly 21 is detachably coupled to the plug 12, and the wire assembly 22 is detachably coupled to the external power apparatus 30, the video apparatus 40, the audio apparatus 50, and the storage apparatus 60. Thus, the electronic device 10 may electrically connected to the external power apparatus 30, the video apparatus 40, the audio apparatus 50, and the storage apparatus 60 through the connector 20. The connector 20 includes an external wall 201 and an end surface 202 opposite to the external wall 201. The end surface 202 is substantially an arcuate surface substantially matching the arc of the end wall 111, so the end surface 202 can be flush with the end wall 111. The contact assembly 21 is arranged on the end surface 202, the wire assembly 22 is arranged on the external wall 201. The contact assembly 21 includes a power transmission contact 211, a ground contact 212, a video transmission contact 213, an audio transmission contact 214, and a data transmission contact 215 for corresponding to the power transmission adapter 121, the ground adapter 122, the video transmission adapter 123, the audio transmission adapter 124, and the data transmission adapter 125 respectively. The power transmission contact 211, the ground contact 212, the video transmission contact 213, the audio transmission contact 214, and the data transmission contact 215 are substantially circular grooves and have inner diameters to match the power transmission adapter 121, the ground adapter 122, the video transmission adapter 123, the audio transmission adapter 124, and the data transmission adapter 125. The power transmission contact 211, the ground contact 212, the video transmission contact 213, the audio transmission contact 214, and the data transmission contact 215 are arranged in a line, for example with their centers on a common line.

The wire assembly 22 includes a power transmission wire 221, a ground wire 222, a video transmission wire 223, an audio transmission wire 224, and a data transmission wire 225. One end of the power transmission wire 221 and the ground wire 222 is electrically connected to the power transmission contact 211 and the ground contact 212. The other end of the power transmission wire 221 and the ground wire 222 is electrically connected to the power apparatus 30. The power apparatus 30 provides power supply to the electronic device 10. The power apparatus 30 can be, but is not limited to, a power adapter and a portable power source. Thus, the electronic device 10 can be charged and grounded by connecting to the power apparatus 30 through the connector 20. One end of the video transmission wire 223 is electrically connected to the video transmission contact 213, the other end is electrically connected to the video apparatus 40 for transmitting video data between the electronic device 10 and the video apparatus 40. In at least one embodiment, the video apparatus 40 can be, but is not limited to, a display and a projector, which can display video data received from the electronic device 10. Thus, the electronic device 10 may output video to the video apparatus 40 through the connector 20 and the video can be displayed by the video apparatus 40. One end of the audio transmission wire 224 is electrically connected to the audio transmission contact 214, the other end is electrically connected to the audio apparatus 50 for transmitting audio data between the electronic device 10 and the audio apparatus 50. In at least one embodiment, the audio apparatus 50 can be, but is not limited to, an earphone and a speaker, which can play audio data received from the electronic device 10. Thus, the electronic device 10 may output the audio to the audio apparatus 50 through the connector 20 and the audio can be played by the audio apparatus 50. One end of the data transmission wire 225 is electrically connected to the data transmission contact 215, the other end is electrically connected to the storage apparatus 60 for transmitting data between the electronic device 10 and the storage apparatus 60. In at least one embodiment, the storage apparatus 60 can be, but is not limited to, a hard disk and a flash memory card, which can store data of and for the electronic device 10. Thus, the electronic device 10 may store the data to and read the data from the storage apparatus 60 through the connector 20.

The connector 20 further includes at least one second magnet element 23. The second magnet element 23 is arranged in the end surface 202. In at least one embodiment, the connector 20 includes two second magnet elements 23 symmetrically arranged on opposite ends of the contact assembly 21 and corresponding to the first magnet elements 23. Each of the second magnet elements 23 is substantially rectangular and can be a magnet or magnetic material.

When the connector 20 is coupled to the electronic device 10, the power transmission contact 211, the ground contact 212, the video transmission contact 213, the audio transmission contact 214, and the data transmission contact 215 are electrically coupled to the power transmission adapter 121, the ground adapter 122, the video transmission adapter 123, the audio transmission adapter 124, and the data transmission adapter 125 respectively. The first magnet elements 13 and the second magnet elements 23 are attracted to each other, thus, the end wall 111 of the electronic device 10 is closely held to the end surface 202 of the connector 20.

The electronic device 10 defines and centralizes a plurality of adapters 121-125, which may be electrically connected to different external apparatus 30-60 through the connector 20. Thus, the electronic device 10 retains all functions in an integrated design with maximum structural strength.

It is believed that the embodiments and their advantages will be understood from the foregoing description, and it will be apparent that various changes may be made thereto without departing from the scope of the disclosure or sacrificing all of its advantages, the examples hereinbefore described merely being illustrative embodiments of the disclosure.

What is claimed is:

1. An electronic device, comprising:
a case having an end wall; and
a plug arranged on the end wall, the plug comprising a power transmission adapter, a ground adapter, a video transmission adapter, an audio transmission adapter, and a data transmission adapter for transmitting power, grounding, transmitting video, audio, and data to the electronic device.

2. The electronic device as claimed in claim 1, wherein the end wall is an arcuate surface, the power transmission adapter, the ground adapter, the video transmission adapter, the audio transmission adapter, and the data transmission adapter are cylindrical and slightly protruded from the end wall; the power transmission adapter, the ground adapter, the video transmission adapter, the audio transmission adapter, and the data transmission adapter are arranged in a line.

3. The electronic device as claimed in claim 1, further comprising at least one first magnet element, wherein the first magnet element is arranged in the end wall.

4. The electronic device as claimed in claim 3, wherein the electronic device comprises two first magnet elements symmetrically arranged on opposite ends of the plug.

5. The electronic device as claimed in claim 3, wherein the at least one first magnet element is rectangular and a magnet or made of magnetic material.

6. The electronic device as claimed in claim 1, wherein the case is made of metal material, the plug is coupled to a central portion of the end wall.

7. A connector detachably coupled to an electronic device, the connector comprising:
an external wall;
an end surface opposite to the external wall;
a contact assembly arranged on the end surface and comprising a power transmission contact, a ground contact, a video transmission contact, an audio transmission contact, and a data transmission contact electrically connected to the electronic device; and
a wire assembly arranged on the external wall and comprising a power transmission wire, a ground wire, a video transmission wire, an audio transmission wire, and a data transmission wire;
wherein one end of the power transmission wire, the ground wire, the video transmission wire, the audio transmission wire, and the data transmission wire are electrically connected to the power transmission contact, the ground contact, the video transmission contact, the audio transmission contact, and the data transmission contact, respectively; the other end are electrically connected to a power apparatus, a video transmission apparatus, an audio transmission apparatus, and a storage apparatus, respectively, for transmitting power, grounding, transmitting video, audio, and data between the electronic device and the apparatuses.

8. The connector as claimed in claim 7, wherein the end surface is an arcuate surface and detachably coupled to the electronic device.

9. The connector as claimed in claim 7, wherein the power transmission contact, the ground contact, the video transmission contact, the audio transmission contact, and the data transmission contact are circular grooves and orderly arranged in a line.

10. The connector as claimed in claim 7, further comprising at least one second magnet element, wherein the at least one second magnet element is arranged in the end surface.

11. The connector as claimed in claim 10, wherein the connector comprises two second magnet elements symmetrically arranged on opposite ends of the contact assembly.

12. The connector as claimed in claim 7, wherein the at least one second magnet element is rectangular and a magnet or made of magnetic material.

13. An electronic device assembly comprising:
an electronic device comprising
a case having an end wall; and
a plug arranged on the end wall, the plug comprising a power transmission adapter, a ground adapter, a video transmission adapter, an audio transmission adapter, and a data transmission adapter;
a connector configured to be detachably coupled to the electronic device, the connector comprising:
an external wall;
an end surface opposite to the external wall;
a contact assembly arranged on the end surface and comprising a power transmission contact, a ground contact, a video transmission contact, an audio transmission contact, and a data transmission contact electrically connected to the power transmission adapter, the ground adapter, the video transmission adapter, the audio transmission adapter, and the data transmission, respectively; and
a wire assembly arranged on the external wall and comprising a power transmission wire, a ground wire, a video transmission wire, an audio transmission wire, and a data transmission wire;
wherein one end of the power transmission wire, the ground wire, the video transmission wire, the audio transmission wire, and the data transmission wire are electrically connected to the power transmission contact, the ground contact, the video transmission contact, the audio transmission contact, and the data transmission contact, respectively; the other end are electrically connected to a power apparatus, a video transmission apparatus, an audio transmission apparatus, and a storage apparatus, respectively, for transmitting power, grounding, transmitting video, audio, and data between the electronic device and the apparatuses.

14. The electronic device assembly as claimed in claim 13, wherein the end wall is an arcuate surface, the end surface is an arcuate surface and resisted to the end wall.

15. The electronic device assembly as claimed in claim 13, wherein the power transmission adapter, the ground adapter, the video transmission adapter, the audio transmission adapter, and the data transmission adapter are cylindrical and slightly protruding from the end wall, and arranged in a line; the power transmission contact, the ground contact, the video transmission contact, the audio transmission contact, and the data transmission contact are circular grooves and arranged in a line.

16. The electronic device assembly as claimed in claim 13, wherein the electronic device further comprises at least one first magnet element arranged in the end wall, the connector further comprises at least one second magnet element arranged in the end surface and is correspondingly attracted to the first magnet element.

17. The electronic device assembly as claimed in claim 16, wherein the electronic device comprises two first magnet elements symmetrically arranged on opposite ends of the plug, the connector comprises two second magnet elements symmetrically arranged on opposite ends of the contact assembly; the two second magnet elements are attracted to the two first magnet elements, respectively.

18. The electronic device assembly as claimed in claim 16, wherein the at least one first magnet element and the at least one second magnet element are rectangular and a magnet or made of magnetic material.

19. The electronic device assembly as claimed in claim 13, wherein the case is made of metal material, the plug is coupled to a central portion of the end wall.
